(19) United States
(12) Patent Application Publication
(10) Pub. No.: US 2012/0161140 A1
(43) Pub. Date: Jun. 28, 2012

(54) TFT ARRAY SUBSTRATE AND MANUFACTURING METHOD THEREOF

(75) Inventors: Hailin XUE, Beijing (CN); Yubo XU, Beijing (CN); Cheng LI, Beijing (CN); Jidong ZHANG, Beijing (CN)

(73) Assignee: BEIJING BOE OPTOELECTRONICS TECHNOLOGY CO., LTD., Beijing (CN)

(21) Appl. No.: 13/332,689

(22) Filed: Dec. 21, 2011

(30) Foreign Application Priority Data
Dec. 22, 2010 (CN) 201010601389.7

(51) Int. Cl. H01L 33/08; H01L 33/62

(52) U.S. Cl. 257/59; 438/34; 257/E33.053; 257/E33.066

(57) ABSTRACT

An thin film transistor array and a manufacturing method thereof are provided. A thin film transistor (TFT) array substrate comprises a base substrate, horizontal gate lines, reticulated storage capacitor electrode (Vcom) lines, longitudinal data lines defining pixel units with the horizontal gate lines. The Vcom lines corresponding to the pixel units in each row of the reticulated Vcom line are connected with each other, and the reticulated Vcom lines are connected with an integrated-circuit (IC) element through Vcom line IC terminals; if the number of the data lines is N, the number of the Vcom line IC terminals is more than 0 and less than N+1; and at least one Vcom line longitudinal electric connection section is provided between the Vcom lines in two adjacent rows.

### BACKGROUND

Embodiments of the disclosed technology pertain to a thin film transistor (TFT) array substrate and a manufacturing method thereof.

Thin film transistor-liquid crystal displays (TFT-LCDs) employ a variable electric field applied onto a liquid crystal layer to control the orientations of liquid crystal molecules and therefore control transmittance of the liquid crystal layer to conduct display of images.

In general, a liquid crystal panel comprises a backlight module, a lower array substrate, an upper color filter substrate and a liquid crystal layer filled into the space formed by combining the two substrates together. Each pixel unit on the array substrate comprises a pixel electrode and a TFT switch element, and the application and amplitudes of the voltage on the pixel electrode are controlled respectively by the gate signals over the gate electrode, connected with a gate line, of the TFT switch element and by the data signal over the source electrode, connected with a data line, of the TFT switch element. The common electrode on the upper color filter substrate cooperates with the pixel electrodes on the lower array substrate to control the orientations of the liquid crystal molecules with the variable electric field produced therebetween. On the array substrate, storage capacitor lines (Vcom lines) that are parallel with and on the same level as the gate lines can form storage capacitors with pixel electrodes therebetween for maintaining the state of the liquid crystal molecules of the corresponding pixel units before arrival of a next driving signal.

An array substrate may be implemented in a dual-gate configuration, which can effectively reduce the amount of data line integrated-circuit (IC) terminals (i.e., connecting parts with a driving IC) and realize the benefits of lowering costs. In order to avoid a greenish defect, a panel with the dual-gate configuration typically adopts a reticulated Vcom line configuration, as shown in FIG. 1. In FIG. 1, the array substrate comprises gate lines 1, data lines 2, Vcom line IC terminals 3, Vcom lines 4 and pixel units 5. The Vcom line IC terminals 3 are the connecting parts of the Vcom lines with a driving IC. From FIG. 1, the Vcom lines 4 for all the pixel units are electrically connected in both the horizontal and the longitudinal directions to form a network configuration, and further the Vcom line IC terminals in the longitudinal direction are arranged alternatively with the data line IC terminals in the longitudinal directions.

In particular, in FIG. 1, the IC terminals from the left side to the right side comprise a Vcom line IC terminal 31, a data line IC terminal 21, a Vcom line IC terminal 32, a data line IC terminal 22, a Vcom line IC terminal 33, a data line IC terminal 23, and a Vcom line IC terminal 34. Given there are N data lines, there would be N+1 Vcom line IC terminals. This alternative configuration gives rise to waste of IC terminals and also results in reduction of aperture ratio of the pixel unites.

### SUMMARY

An embodiment of the disclosed technology provides a thin film transistor (TFT) array substrate, comprising: a base substrate; horizontal gate lines; reticulated storage capacitor electrode (Vcom) lines; longitudinal data lines defining pixel units with the horizontal gate lines; wherein the Vcom lines corresponding to the pixel units in each row of the reticulated Vcom line are connected with each other, and the reticulated Vcom lines are connected with an integrated-circuit (IC) element through Vcom line IC terminals; if the number of the data lines is N, the number of the Vcom line IC terminals is more than 0 and less than N+1; and at least one Vcom line longitudinal electric connection section is provided between the Vcom lines in two adjacent rows.

Another embodiment of the disclosed technology provides a method for manufacturing a thin film transistor (TFT) array substrate comprising: forming a first conductive film on a base substrate and patterning the first conductive film to form gate lines and storage capacitor electrode (Vcom) lines, wherein the Vcom lines corresponding to pixel units in each row are connected with each other; forming a second conductive film on the base substrate and patterning the second conductive film to form data lines; and forming a pixel electrode thin film layer on the base substrate and patterning the pixel electrode thin film layer to form pixel electrodes, longitudinal Vcom line electric connection sections between the Vcom lines in two adjacent rows, and Vcom line IC terminals; wherein if the number of the data lines is N, the number of the Vcom line IC terminals is more than 0 and less than N+1; and at least one Vcom line longitudinal electric connection section is provided between the Vcom lines in two adjacent rows.

Further scope of applicability of the disclosed technology will become apparent from the detailed description given hereinafter. However, it should be understood that the detailed description and specific examples, while indicating preferred embodiments of the invention, are given by way of illustration only, since various changes and modifications within the spirit and scope of the disclosed technology will become apparent to those skilled in the art from the following detailed description.

### BRIEF DESCRIPTION OF THE DRAWINGS

The disclosed technology will become more fully understood from the detailed description given hereinafter and the accompanying drawings which are given by way of illustration only, and thus are not limitative of the disclosed technology and wherein:

FIG. 1 shows a structural schematic view of a conventional dual-gate TFT array substrate;

FIG. 2 shows a structural schematic view of the dual-gate TFT array substrate according to an embodiment of the disclosed technology;

FIG. 3 shows a structural schematic view of the dual-gate TFT array substrate according to another embodiment of the disclosed technology;

FIG. 4 shows a structural schematic view of the dual-gate TFT array substrate according to still another embodiment of the disclosed technology;

FIG. 5 shows a first schematic view of the method for manufacturing a dual-gate TFT array substrate according to an embodiment of the disclosed technology;

FIG. 6 shows a second schematic view of the method for manufacturing a dual-gate TFT array substrate according to the embodiment of the disclosed technology;

FIG. 7 shows a third schematic view of the method for manufacturing a dual-gate TFT array substrate according to the embodiment of the disclosed technology; and

FIG. 8 shows a fourth schematic view of the method for manufacturing a dual-gate TFT array substrate according to the embodiment of the disclosed technology.

### DETAILED DESCRIPTION

The technical solutions of the embodiments of the disclosed technology will be described clearly and completely in combination with the drawings of the embodiments of the disclosed technology. Obviously, the described embodiments are a part of the embodiments of the disclosed technology, but not all the embodiments. Based on the embodiments of the disclosed technology, the other embodiments obtained by those skilled in the related art without inventive work fall within the scope of the disclosed technology.

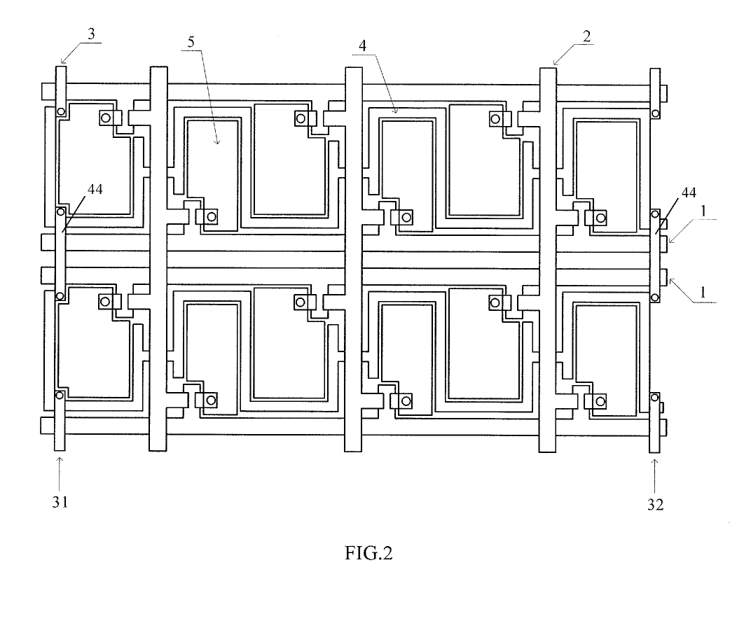

As shown in FIG. 2, an embodiment of the disclosed technology provides a dual-gate TFT array substrate, which comprises a glass substrate (not shown in the drawing), and horizontal gate lines 1, reticulated Vcom lines 4, longitudinal data lines 2, and pixel units 5 defined by the horizontal gate lines 1 and longitudinal data lines 2, which are formed on the glass substrate as a base substrate. The Vcom lines, corresponding to respective pixel units, of the reticulated Vcom line 4 in each row are connected with each other, and Vcom lines 4 are connected to the IC driver through the Vcom line IC terminals 3.

If the number of the data lines 2 of the TFT array substrate according to the embodiment is N, then the number of the Vcom line IC terminals 3 in this embodiment is more than 0 and less than N+1. For example, the number of the data lines 2 is 3 (i.e., N=3), the number of the Vcom line IC terminals 3 is 2, that is, 0<2<(3+1), satisfying the requirement that the number of the Vcom line IC terminals 3 is more than 0 and less than N+1.

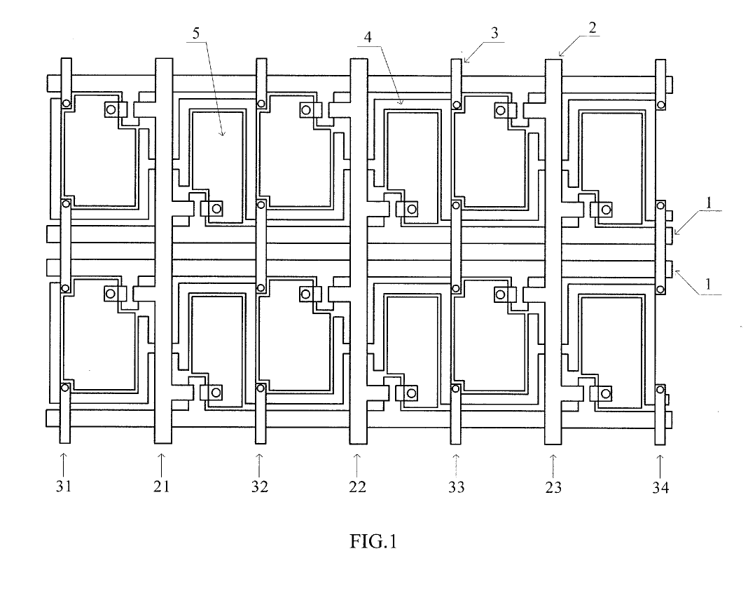

For the technology as shown in FIG. 1, if the Vcom line IC terminals are arranged alternatively with the data lines, there are four (4) Vcom line IC terminals in the case where there are three (3) data lines. Therefore, it can be seen that in this embodiment of the disclosed technology only two (2) Vcom line IC terminals are needed in the same case where there are three (3) data lines. The experiments made by the inventors show that more than one Vcom line IC terminal can used to avoid the greenish defect, thus the embodiment of the disclosed technology can reduce the number of used IC terminals while avoids the greenish defect and improves aperture ratio of the relevant pixel units.

In addition, there are at least one set of longitudinal electric connection sections between the Vcom lines 4 in two adjacent rows for the Vcom lines 4. In this embodiment, as shown in FIG. 2, among the Vcom lines 4 in two adjacent rows, there is one set of longitudinal electric connection sections 44 for the Vcom lines 4 corresponding to each of the Vcom line IC terminals 3 in the longitudinal direction, i.e., the Vcom line IC terminals 31, 32. However, the disclosed technology is not limited thereto, between the Vcom lines 4 in two adjacent rows, there may be more longitudinal electric connection sections for Vcom lines in the longitudinal direction than the Vcom line IC terminals 3.

In the dual-gate TFT array substrate provided in the embodiment of the disclosed technology, where N data lines are provided, the number of the Vcom line IC terminals is more than 0 and less than N+1, and there are at least one set of longitudinal electric connection section for Vcom line between the Vcom lines in two adjacent rows. In this way, the number of the Vcom line IC terminals on the TFT array substrate can be reduced, and accordingly the costs for manufacturing the TFT array substrate is lowered, and the aperture ratio of the pixel units in which no Vcom line IC terminals and no Vcom line longitudinal electric connection sections are provided can be increased. In addition, because the number of the Vcom line IC terminals is still more than 0, the greenish defect can be avoided as well.

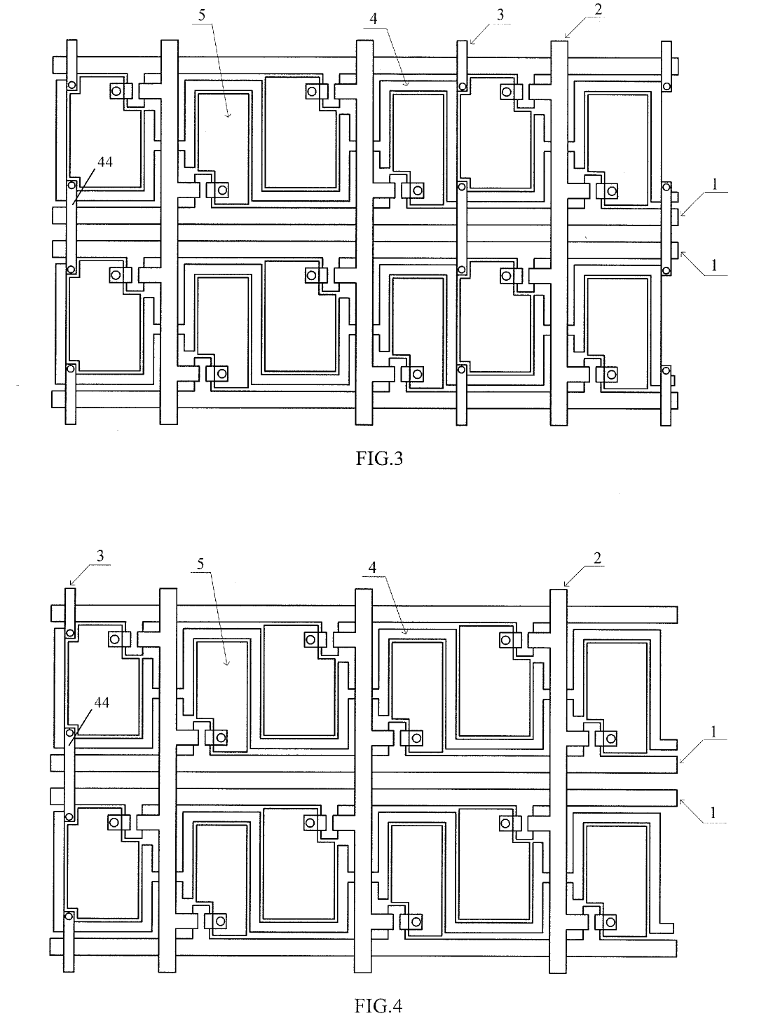

Of course, the two extreme cases include: compared with the conventional alternative arrangement of the Vcom line IC terminals and the data lines, the embodiment of the disclosed technology reduces the number of the Vcom line IC terminals by one only (as shown in FIG. 3), and reduces the number of the Vcom line IC terminals to only one (as shown in FIG. 4). In other words, compared with the conventional alternative arrangement, the embodiment of the disclosed technology can reduce the number of the Vcom line IC terminals from that reduced by one only to only one Vcom line IC terminal in theory.

When the number of the Vcom line IC terminals is reduced by one only, as shown in FIG. 3, if there are two (2) data lines 2, the number of the Vcom line IC terminals 3 is 3, 0<3<(3+1), which satisfies the requirement that the number of the Vcom line IC terminals 3 is more than 0 and less than N+1; meanwhile, when the number of the Vcom line IC terminals is reduced to only one, as shown in FIG. 4, if there are three (3) data lines 2, the number of the Vcom line IC terminals 3 is 1, 0<1<(3+1), which satisfies the requirement that the number of the Vcom line IC terminals 3 is more than 0 and less than N+1.

In FIG. 3 and FIG. 4, between the Vcom lines 4 in two adjacent rows, there are sets of Vcom line longitudinal electric connection sections 44 respectively corresponding to the Vcom line IC terminals 3 in the longitudinal direction. That is, in FIG. 3, there are three (3) corresponding sets of longitudinal electric connection sections for the Vcom lines 4; in FIG. 4, there is one (1) corresponding set of longitudinal electric connection section for the Vcom lines 4.

An embodiment of the disclosed technology provides a method for manufacturing a dual-gate TFT array substrate, which comprises the following steps.

S501, forming a first conductive film on a base substrate and patterning the first conductive film with a patterning process to form gate lines and Vcom lines; the Vcom lines corresponding to the pixel units in each row are connected with each other.

In an example, with a magnetron sputtering method, a metal thin film with a thickness of 1000 Å through 7000 Å is formed on a base substrate such as a glass substrate. The material of the metal thin film may be molybdenum, aluminum, aluminum nickel alloy, molybdenum tungsten alloy, chromium, copper or the like, and may be a multiple-layer structure formed with the one or more of the above-described metal materials. Then, the metal thin film is patterned with a patterning process with a mask plate, comprising exposing, developing, etching, photoresist removing, and so on, as shown in FIG. 5, to form gate lines 1 and Vcom lines 4 running in the horizontal direction in certain regions on the glass substrate; gate electrodes of the TFTs are connected with the gate lines, and Vcom lines 4 corresponding to the pixel units (i.e., in each of the pixel units) in each row are connected with each other.

S502, forming a gate insulation layer on the gate lines, then forming an active layer on the gate insulation layer corresponding to gate electrodes connected with the gate lines.

In an example, a gate insulation layer of a thickness of 1000 Å to 6000 Å and an amorphous silicon thin film of a thickness of 1000 Å to 6000 Å can be sequentially formed with a chemical vapor deposition (CVD) method on the glass substrate. The material of the gate insulation layer may be silicon nitride, silicon oxide, or silicon oxynitride. A photoresist etching pattern is obtained with a mask plate for exposing, then the amorphous silicon thin film is subject to a dry etching process, an active layer in an island structure or a peninsula structure can be formed on each gate electrode.

S503, forming a second conductive film on the base substrate and patterning the second conductive film with a patterning process to form data lines.

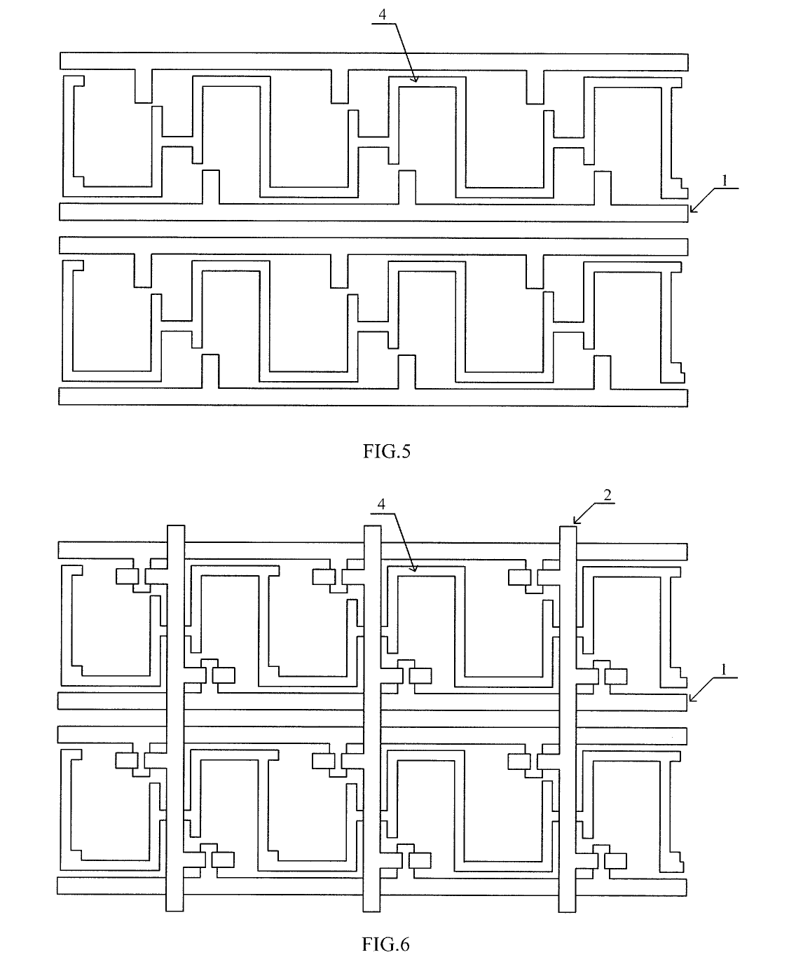

In an example, with a similar process to that for forming the gate lines, a metal thin film with a thickness of 1000 Å to 7000 Å is formed on the glass substrate, the material of which is similar to that for gate lines. As shown in FIG. 6, the metal thin film is patterned by a patterning process with a mask plate to form data lines 2 and source electrodes and drain electrodes of thin film transistors (TFTs), and channels of the active layers are defined between the source electrodes and the drain electrodes, thus the source electrodes, the drain electrodes, the active layers and the previously formed gate electrodes together constitute TFTs.

S504, forming a transparent passivation layer on the data lines and forming via holes at the positions over the drain electrodes and the Vcom lines.

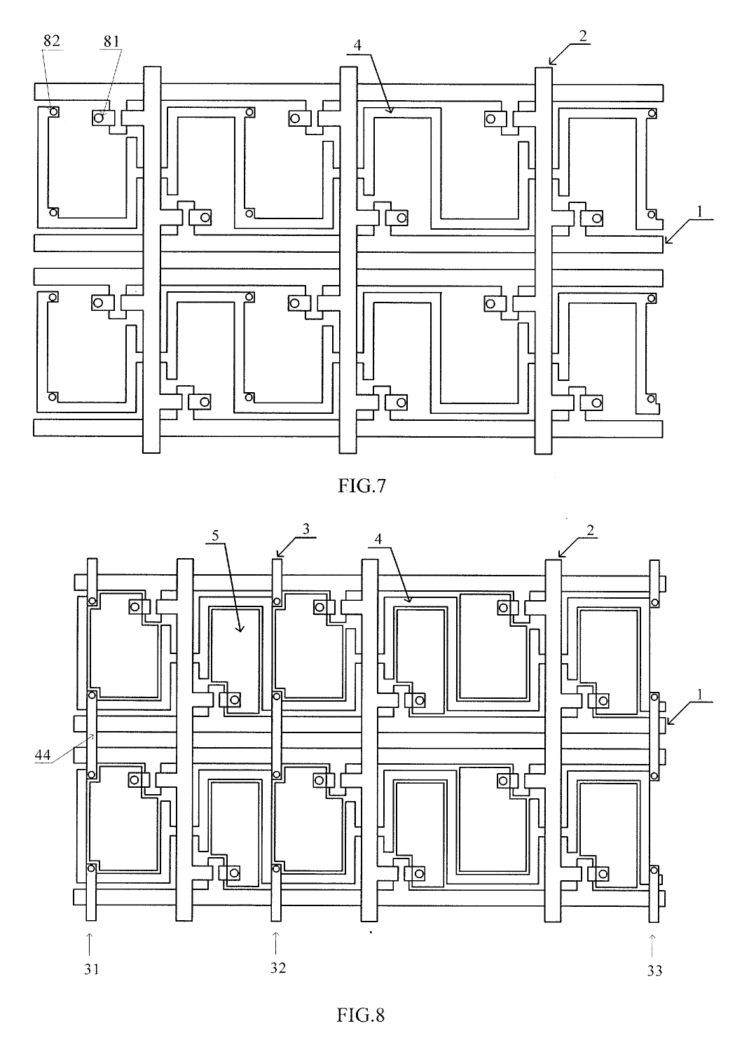

In an example, with a similar process to that for forming the gate insulation layer or the active layer, a passivation layer with a thickness of 1000 Å to 6000 Å is formed (e.g., coated) over the entire glass substrate, the material of which may be silicon nitride or a transparent organic resin material. Here, the gate lines and the data lines are overcoated with the passivation layer of the same thickness. As shown in FIG. 7, the passivation layer is patterned with a patterning process, and connecting via holes 81, 82 are formed at the positions corresponding to the drain electrodes and the Vcom lines.

S505, forming a pixel electrode thin film layer on the transparent passivation layer.

In an example, a pixel electrode thin film layer is deposited on the passivation layer over the entire glass substrate. The material of the pixel electrode thin film layer may be ITO (Indium Tin Oxide) or IZO (Indium Zinc Oxide) and of a thickness of 100 Å to 1000 Å.

S506, patterning the pixel electrode thin film layer on the base substrate with a patterning process to form pixel electrodes 5 of the pixel units, longitudinal electric connection sections 44 between the Vcom lines 4 in two adjacent rows, and Vcom line IC terminals 3, as shown in FIG. 8. If the number of the data lines 2 is N, the number of the Vcom line IC terminals 3 is more than 0 and less than N+1, and there is at least one Vcom line longitudinal electric connection section 44 between the Vcom lines 4 in two adjacent rows, thus the Vcom lines 4 are reticulated, that is, form a network configuration, on the base substrate.

In this embodiment, as shown in FIG. 2, between the Vcom lines 4 in two adjacent rows, there is one set of Vcom line longitudinal electric connection sections 44 corresponding to each Vcom line IC terminal 3 in the longitudinal direction, i.e., there are two sets of Vcom line longitudinal electric connection section respectively corresponding to the Vcom line IC terminals 31, 32; however the disclosed technology is not limited thereto, between the Vcom lines 4 in two adjacent rows the number of the sets of longitudinal electric connection sections 44 may be more than that of the Vcom line IC terminals 3.

In the TFT array substrate obtained by the method for manufacturing the dual-gate TFT array substrate according to the embodiment of the disclosed technology, when the number of the data lines is N, the number of the Vcom line IC terminals is more than 0 and less than N+1; furthermore, there is at least one corresponding set of Vcom line longitudinal electric connection section between the Vcom lines in two adjacent rows. The number of the Vcom line IC terminals on the TFT array substrate can be reduced, and accordingly the costs for manufacturing the TFT array substrate can be lowered, and the aperture ratio of the pixel units where no Vcom line IC terminals and no Vcom line longitudinal electric connection sections are provided can be increased. In addition, because the number of the Vcom line IC terminals is still more than 0, the greenish defect can be avoided as well.

Of course, the two extreme cases are: compared with the conventional alternative arrangement of the Vcom line IC terminals and the data lines, the embodiment of the disclosed technology reduces the number of the Vcom line IC terminals by one only (as shown in FIG. 3), and reduces the number of the Vcom line IC terminals to only one (as shown in FIG. 4). In other words, compared with the conventional alternative arrangement, the embodiment of the disclosed technology can reduce the number of the Vcom line IC terminals from that reduced by one only to only one Vcom line IC terminal in theory.

In the above description, a dual-gate TFT array substrate is taken for example; however those skilled in the art should understand that the scope of the disclosed technology is not limited thereto, and the embodiment of the disclosed technology can also be applied to other types of TFT array substrates which comprise Vcom lines.

The embodiment of the disclosed technology being thus described, it will be obvious that the same may be varied in many ways. Such variations are not to be regarded as a departure from the spirit and scope of the disclosed technology, and all such modifications as would be obvious to those skilled in the art are intended to be included within the scope of the following claims.

What is claimed is:

1. A thin film transistor (TFT) array substrate, comprising:
a base substrate;
horizontal gate lines;
reticulated storage capacitor electrode (Vcom) lines;
longitudinal data lines defining pixel units with the horizontal gate lines;
wherein the Vcom lines corresponding to the pixel units in each row of the reticulated Vcom line are connected with each other, and the reticulated Vcom lines are connected with an integrated-circuit (IC) element through Vcom line IC terminals;
if the number of the data lines is N, the number of the Vcom line IC terminals is more than 0 and less than N+1; and
at least one Vcom line longitudinal electric connection section is provided between the Vcom lines in two adjacent rows.

2. The TFT array substrate according to claim 1, wherein the number of the Vcom line IC terminals is N.

3. The TFT array substrate according to claim 1, wherein the number of the Vcom line IC terminals is 1.

4. The TFT array substrate according to claim 1, wherein one set of Vcom line longitudinal electric connection sections each between Vcom lines in two adjacent rows is provided corresponding to one of the Vcom line IC terminals in the longitudinal direction.

5. The TFT array substrate according to claim 2, wherein one set of Vcom line longitudinal electric connection sections each between Vcom lines in two adjacent rows is provided corresponding to one of the Vcom line IC terminals in the longitudinal direction.

6. The TFT array substrate according to claim 3, wherein one set of Vcom line longitudinal electric connection sections each between Vcom lines in two adjacent rows is provided corresponding to one of the Vcom line IC terminals in the longitudinal direction.

7. A method for manufacturing a thin film transistor (TFT) array substrate comprising:
forming a first conductive film on a base substrate and patterning the first conductive film to form gate lines and storage capacitor electrode (Vcom) lines, wherein the Vcom lines corresponding to pixel units in each row are connected with each other;
forming a second conductive film on the base substrate and patterning the second conductive film to form data lines; and
forming a pixel electrode thin film layer on the base substrate and patterning the pixel electrode thin film layer to form pixel electrodes, longitudinal Vcom line electric connection sections between the Vcom lines in two adjacent rows, and Vcom line IC terminals;
wherein if the number of the data lines is N, the number of the Vcom line IC terminals is more than 0 and less than N+1; and
at least one Vcom line longitudinal electric connection section is provided between the Vcom lines in two adjacent rows.

8. The method according to claim 7, wherein the number of the Vcom line IC terminals is N.

9. The method according to claim 7, wherein the number of the Vcom line IC terminal is 1.

10. The method according to claim 7, wherein one set of Vcom line longitudinal electric connection sections each between Vcom lines in two adjacent rows is provided corresponding to one of the Vcom line IC terminals in the longitudinal direction.

11. The method according to claim 8, wherein one set of Vcom line longitudinal electric connection sections each between Vcom lines in two adjacent rows is provided corresponding to one of the Vcom line IC terminals in the longitudinal direction.

12. The method according to claim 9, wherein one set of Vcom line longitudinal electric connection sections each between Vcom lines in two adjacent rows is provided corresponding to one of the Vcom line IC terminals in the longitudinal direction.
